(19) United States
(12) Patent Application Publication
(10) Pub. No.: US 2014/0312299 A1
(43) Pub. Date: Oct. 23, 2014

(54) LIGHT EMITTING DIODE CHIP

(71) Applicant: ADVANCED OPTOELECTRONIC TECHNOLOGY, INC., Hsinchu Hsien (TW)

(72) Inventors: CHIA-HUI SHEN, Hukou (TW); TZU-CHIEN HUNG, Hukou (TW)

(73) Assignee: ADVANCED OPTOELECTRONIC TECHNOLOGY, INC., Hsinchu Hsien 303 (TW)

(21) Appl. No.: 14/200,028

(22) Filed: Mar. 7, 2014

(30) Foreign Application Priority Data
Apr. 18, 2013 (CN) 2013101355336

(51) Int. Cl. H01L 33/22; H01L 33/06

(52) U.S. Cl. CPC H01L 33/22; H01L 33/06
USPC 257/13

(57) ABSTRACT

A light emitting diode (LED) includes a substrate, a semiconductor structure formed on the substrate, and two electrodes formed on the semiconductor structure. The semiconductor structure includes a bearing surface via which light generated by the semiconductor structure radiates out of the LED. A plurality of microstructures is formed on the bearing surface. A cross section of each microstructure is rectangular triangular having a vertical side surface. Each microstructure includes a top surface. The top surface is inclined relative to the bearing surface.

### BACKGROUND

1. Technical Field

The disclosure relates to semiconductors, and more particularly to a light emitting diode (LED) chip with high light emitting efficiency.

2. Description of the Related Art

LEDs have low power consumption, high efficiency, quick reaction time, long lifetime, and the absence of toxic elements such as mercury during manufacturing. Due to those advantages, traditional light sources are gradually replaced by LEDs.

A conventional LED chip includes a substrate and a semiconductor structure formed on a top surface of the substrate. The semiconductor structure includes a bearing surface. The bearing surface is usually etched by photo lithography method to form patterns for avoiding light being totally reflected back into the semiconductor structure, and thereby the light emitting efficiency of the LED chip is increased. However, because the bearing surface only can be etched to form patterns with flat top surfaces by traditional photo lithography method, a part of light emitted by the LED chip is still easily totally reflected by the bearing surface and can not radiate out. Such that, the light emitting efficiency of the LED chip can not be totally satisfied.

Therefore, it is desirable to provide an LED chip with high light emitting efficiency.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present LED chip. Moreover, in the drawings, all the views are schematic, and like reference numerals designate corresponding parts throughout the views.

FIG. 1 is a schematic, cross-sectional view of an LED chip in accordance with a first exemplary embodiment of the present disclosure.

FIG. 2 is a partially enlarged view of an encircled portion II of the LED light chip of FIG. 1.

FIG. 3 is a schematic, cross-sectional view of an LED chip in accordance with a second exemplary embodiment of the present disclosure.

### DETAILED DESCRIPTION

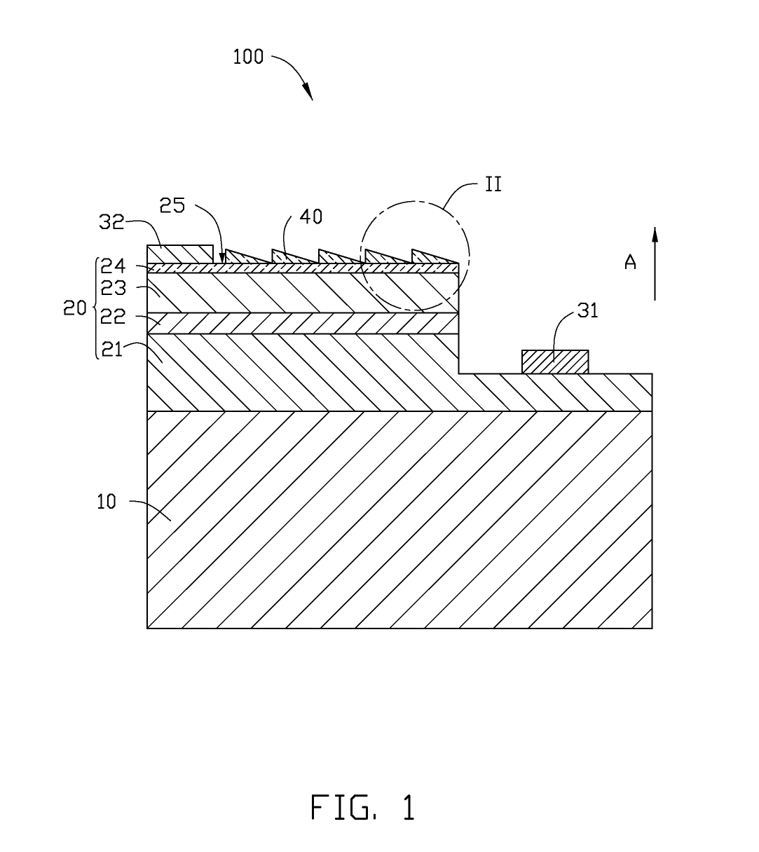

Referring to FIG. 1, an LED chip 100 in accordance with a first embodiment is provided. The LED chip 100 includes a substrate 10, a semiconductor structure 20 formed on the substrate 10, a first electrode 31 and a second electrode 32 formed on the semiconductor structure 20, and a plurality of microstructures 40 formed on the semiconductor structure 20.

The substrate 10 is flat and made of sapphire (Al₂O₃). Alternatively, the substrate 10 also can be made of silicon carbide (SiC), silicon or gallium nitride (GaN).

The semiconductor structure 20 includes a first semiconductor layer 21, a light emitting layer 22, a second semiconductor layer 23 and a conductive layer 24 formed on the substrate 10 in series along a height direction of the LED chip 100. Specifically, the first semiconductor layer 21, the light emitting layer 22, the second semiconductor layer 23 and the conductive layer 24 are formed on the substrate 10 in series along the height direction of the LED chip 100 by metal-organic chemical vapor deposition (MOCVD), molecular beam epitaxy (MBE) or hydride vapor phase epitaxy (HVPE).

The conductive layer 24, the second semiconductor layer 23 and the light emitting layer 22 are partially etched downward to expose a part of the first semiconductor layer 21. In this embodiment, the first semiconductor layer 21 is an N-type GaN layer. The light emitting layer 22 is a multiple quantum well (MQW) GaN/InGaN layer, and the second semiconductor layer 23 is a P-type GaN layer. The conductive layer 24 includes a bearing surface 25 via which light generated by the light emitting layer 22 radiates out of the LED 100. The conductive layer 24 can be made of indium tin oxide (ITO) or an alloy of nickel and gold (Ni/Au) for introducing current from the second electrode 32 evenly into the second semiconductor layer 23 of the semiconductor structure 20 of the LED chip 100.

The second electrode 32 is formed on a top surface of the conductive layer 24. The first electrode 31 and the second electrode 32 guide current to flow through the LED chip 100 for producing an electric field. In this embodiment, the first electrode 31 is a cathode and the second electrode 32 is an anode. Vapor deposition or sputter can be used to form the first electrode 31 and the second electrodes 32.

Each of the microstructures 40 extends outward (i.e., upwardly) from the bearing surface 25 of the conductive layer 24. The microstructures 40 are made of transparent materials such as SiOx, SiNx, ITO, epoxy, silicon as so on by nanoimprint method.

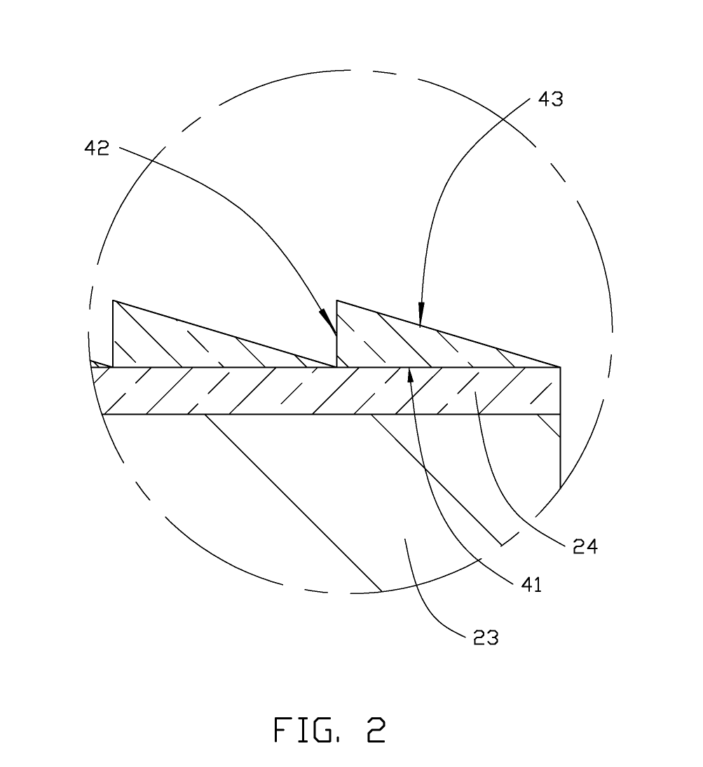

Referring to FIG. 2, in this embodiment, a cross section of each of the microstructures 40 is triangular. An arranged direction A is a direction along which the first semiconductor layer 21, the light emitting layer 22, the second semiconductor layer 23 and the conductive layer 24 are successively formed on the substrate 10. Each of the microstructures 40 includes a bottom surface 41 directly formed on the bearing surface 25, a side surface 41 perpendicularly extending from the bottom surface 41 and vertical to the bearing surface 25, and a top surface 43 interconnecting the bottom surface 41 and the side surface 42. The configuration of the microstructures 40 is similar to a configuration of a surface of a glowing organ such as an abdomen of a glowworm (firefly): a series of triangles each having a bottom surface with a length of about 10 um and a vertical side surface with a height of about 3 um. Accordingly, the bottom surface 41 has a length of about 10 um and the side surface 42 has a height of about 3 um. The bottom surface 41 is perpendicular to the direction A, while the side surface 42 is aligned with (parallel to) the direction A. The top surface 43 is inclined relative to the bearing surface 25 and the direction A. A right, bottom end of the top surface 43 of a microstructure 40 abuts a bottom end of the side surface 42 of an adjacent microstructures 40. Thus, the microstructures 40 form a series of continuous triangles along a horizontal direction of the LED chip 100 on the bearing surface 25. Light emitted from the semiconductor structure 20 enters the microstructures 40 via the bottom surfaces 31, and radiates out via the side surfaces 42 and the top surfaces 43. The part of the light entering the microstructures 40 which impinges on the side surfaces 42 and reflected thereby travels to the top surfaces 43 and radiates out therefrom. Accordingly, no part of the light emitted from the light emitting layer 22 will be reflected by the bearing surface 25 or the microstructures 40 to return into the LED 100.

Compared to the traditional microstructures each with a flat top surface, when the light from the semiconductor structure 20 arrives the top surface 43, since the flat top surface 43 is an inclined top surface, which results in a direction of a normal line vertical to the top surface 43 being changed to be inclined, an incident angle of a part of light which is originally totally reflected by the flat top surface is reduced to be smaller than a critical angle of total reflection, and the part of light originally being totally reflected will radiate out via the top surface 43 of the microstructure 40. Such that, the light emitting efficiency of the LED chip 100 is enhanced.

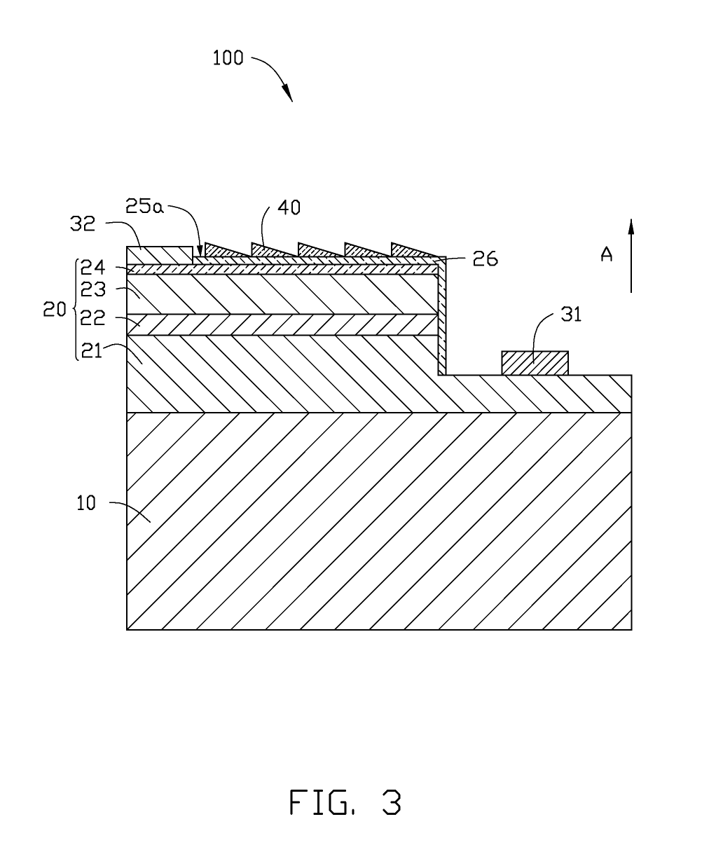

Referring to FIG. 3, an insulating layer 26 is further formed on the conductive layer 24 and extends to the exposed surface of the first semiconductor layer 21 by successively covering side surfaces of the conductive layer 24, the second semiconductor layer 23, the light emitting layer 22 and a part of the first semiconductor layer 21. The insulating layer 26 protects the fist electrode 31 from short-circuit with the second electrode 32. In this embodiment, the insulating layer 26 is made of silicon dioxide (SiO₂).

Alternatively, the insulating layer 26 could also totally cover the conductive layer 24 and the exposed surface of the first semiconductor layer 21 except the first electrode 31 and the second electrode 32, and a top surface of the insulating layer 26 will be regarded as a bearing surface 25a, wherein the microstructures 40 are formed on the bearing surface 25a.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A light emitting diode (LED) chip, comprising:
a substrate;
a semiconductor structure formed on the substrate, the semiconductor structure comprising a bearing surface via which light generated by the semiconductor structure radiates out of the LED chip;
two electrodes formed on the semiconductor structure; and
a plurality of microstructures formed on the bearing surface, a cross section of each of the microstructures being triangular, each of the microstructures comprising a bottom surface in contact with the bearing surface, a side surface perpendicularly extending upwardly from the bearing surface, and a top surface interconnecting the bottom surface and the side surface, the top surface being inclined relative to the bearing surface.

2. The LED chip of claim 1, wherein the microstructures are continuously connected with each other.

3. The LED chip of claim 1, wherein the bottom surface has a length of 10 um and the side surface has a height of 3 um.

4. The LED chip of claim 2, wherein the bottom surface has a length of 10 um and the side surface has a height of 3 um.

5. The LED chip of claim 1, wherein the semiconductor structure comprises a first semiconductor layer, a light emitting layer, a second semiconductor layer and a conductive layer formed on the substrate in series along a height direction of the LED chip, the two electrodes respectively being formed on the first semiconductor layer and the conductive layer, a top surface of the conductive layer being regarded as the bearing surface.

6. The LED chip of claim 5, wherein the first semiconductor layer is an N-type GaN layer, the light emitting layer being a multiple quantum well layer, the second semiconductor layer being a P-type GaN layer, and the conductive layer being made of indium tin oxide.

7. The LED chip of claim 1, wherein the semiconductor structure comprises a first semiconductor layer, a light emitting layer, a second semiconductor, a conductive layer and an insulating layer formed on the substrate in series along a height direction of the LED chip, the two electrodes respectively being formed on the first semiconductor layer and the conductive layer, a top surface of the insulating layer being regarded as the bearing surface.

8. The LED chip of claim 7, wherein the first semiconductor layer is an N-type GaN layer, the light emitting layer being a multiple quantum well layer, the second semiconductor layer being a P-type GaN layer, the conductive layer being made of indium tin oxide, and the insulating layer being made of silicon dioxide.

9. The LED chip of claim 1, wherein the microstructures are made of transparent material selected from a group consisting of SiOx, SiNx, ITO, epoxy and silicon.

10. The LED chip of claim 9, wherein the bottom surface has a length of 10 um and the side surface has a height of 3 um.

11. An LED chip comprising:
a first semiconductor layer;
a light emitting layer on the first semiconductor layer;
a second semiconductor on the light emitting layer; and
a microstructure layer on the second semiconductor layer, the microstructure layer having a plurality of microstructures each having a cross section of a rectangular triangle having a vertical side surface.

12. The LED chip of claim 11, wherein the rectangular triangle has a bottom surface with a length of 10 um and the vertical side surface has a height of 3 um.

13. The LED chip of claim 11 further comprising a conductive layer on the second semiconductor layer, the microstructure layer being on the conductive layer.

14. The LED chip of claim 13, wherein the rectangular triangle has a bottom surface with a length of 10 um and the vertical side surface has a height of 3 um.

15. The LED chip of claim 13 further comprising a transparent insulating layer on the conductive layer, the microstructure layer being on the transparent insulating layer.

16. The LED chip of claim 15, wherein the rectangular triangle has a bottom surface with a length of 10 um and the vertical side surface has a height of 3 um.
